(19) United States
(12) Patent Application Publication
(10) Pub. No.: US 2002/0066592 A1
(43) Pub. Date: Jun. 6, 2002

(54) Ball grid array package capable of increasing heat-spreading effect and preventing electromagnetic interference

(76) Inventor: Wen Feng Cheng, Taoyuan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/727,477

(22) Filed: Dec. 4, 2000

(51) Int. Cl. H05K 1/16

(52) U.S. Cl. 174/260

(57) ABSTRACT

The present invention proposes a BGA package capable of increasing heat-spreading effect and preventing EMI. The BGA package of the present invention comprises a BGA substrate with a conductive ring formed on the periphery thereof. The BGA substrate has a metal layer electrically connected to the conductive ring. At least an IC chip is arranged on the BGA substrate. A cap capable of conducting both electricity and heat covers over the chip. The periphery of the cap is sealed with the conductive ring. Raise parts formed in the cap contacts with the chip to conduct heat out. Moreover, the cap, the conductive ring, and the metal layer can form a shield of EMI for the chip.

### FIELD OF THE INVENTION

The present invention relates to a ball grid array package and, more particularly, to a ball grid array package capable of increasing heat-spreading effect and preventing electromagnetic interference.

### BACKGROUND OF THE INVENTION

Along with the progress of semiconductor fabrication process and the continual enhancement of circuit functions on a chip, the development of integrated circuit (IC) technology tends to high integration. Therefore, the counts of I/O contacts on a chip increase greatly. This development causes the trouble in packaging a chip, especially the heat-spreading problem of the chip.

FIG. 1 shows a ball grid array (BGA) package of flip chip structure. As shown in the figure, a plurality of bumps 12 formed on the surface of a chip 10 are soldered to a BGA substrate 14. The BGA substrate 14 has a plurality of vias 152, each being connected to a solder ball 144.

The above structure has the characteristics of high density, small volume, and high reliability. However, along with the development of ICs toward large I/O counts and high-frequency operation, the chip 10 may burn out easily because of heat generated during operation. Therefore, how to provide a proper heat-spreading means for the chip 10 becomes an important issue.

Attaching a heat spreader on the chip 10 can increase heat-spreading effect. However, this method accompanies the hazard of crushing the chip 10. In U.S. Pat. No. 5,219,794, a heat-spreading cap is exploited to contact with the surface of the chip so as to take heat away. The heat-spreading cap is connected to the substrate via soldering paste. Although this structure can support the heat-spreading cap through the substrate, it is difficult to control the height of the soldering paste so that the chip may be destroyed when installing the heat-spreading cap.

Another disadvantage of the prior art is that it can not protect the chip from electromagnetic interference (EMI). This will cause an IC operating at a high frequency to influence other neighboring devices or to be influenced by the external environment.

### SUMMARY OF THE INVENTION

Accordingly, the primary object of the present invention is to propose a BGA package capable of increasing heat-spreading effect and preventing EMI.

Another object of the present invention is to propose a BGA package, which can prevent a superimposed heat-spreading device from crushing an IC chip.

According to the present invention, a BGA package capable of increasing heat-spreading effect and preventing EMI comprises a BGA substrate with a conductive ring formed on the periphery thereof. At least an IC chip is arranged on the BGA substrate. A cap capable of conducting both electricity and heat encircles the chip. The periphery of the cap is sealed with the conductive ring. Raise parts formed in the cap contacts with the chip to conduct out heat thereof.

The various objects and advantages of the present invention will be more readily understood from the following detailed description when read in conjunction with the appended drawings, in which:

### BRIEF DESCRIPTION OF THE DRAWINGS

FIG. 1 is a schematic cross-sectional view of a prior art BGA package of flip chip structure;

FIG. 2 is a cross-sectional view according to an embodiment of the present invention;

FIG. 3 is a partly cross-sectional view of the substrate of the device shown in FIG. 2;

FIG. 4 is a top view of the device shown in FIG. 2.

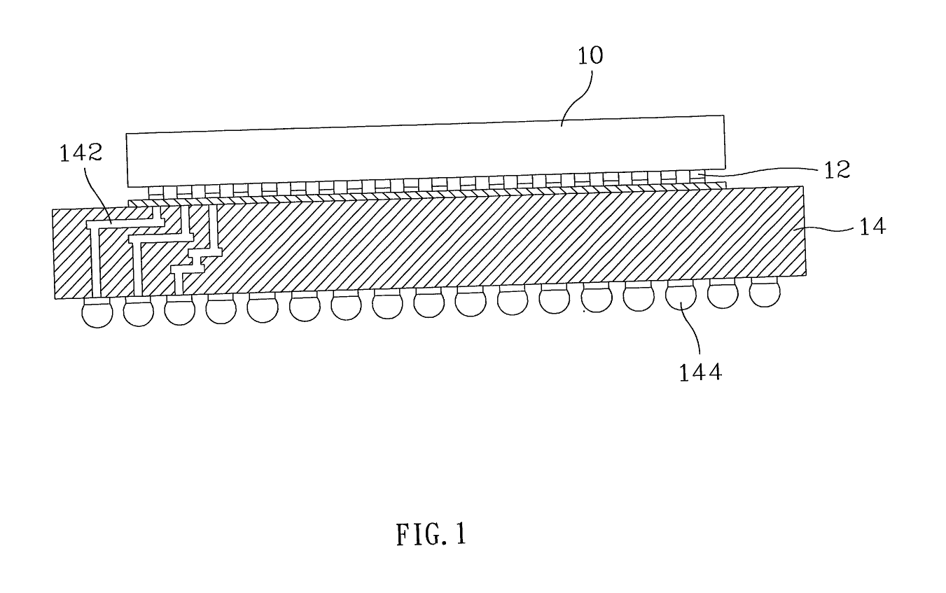

### DETAILED DESCRIPTION OF THE PREFERRED EMBODIMENTS

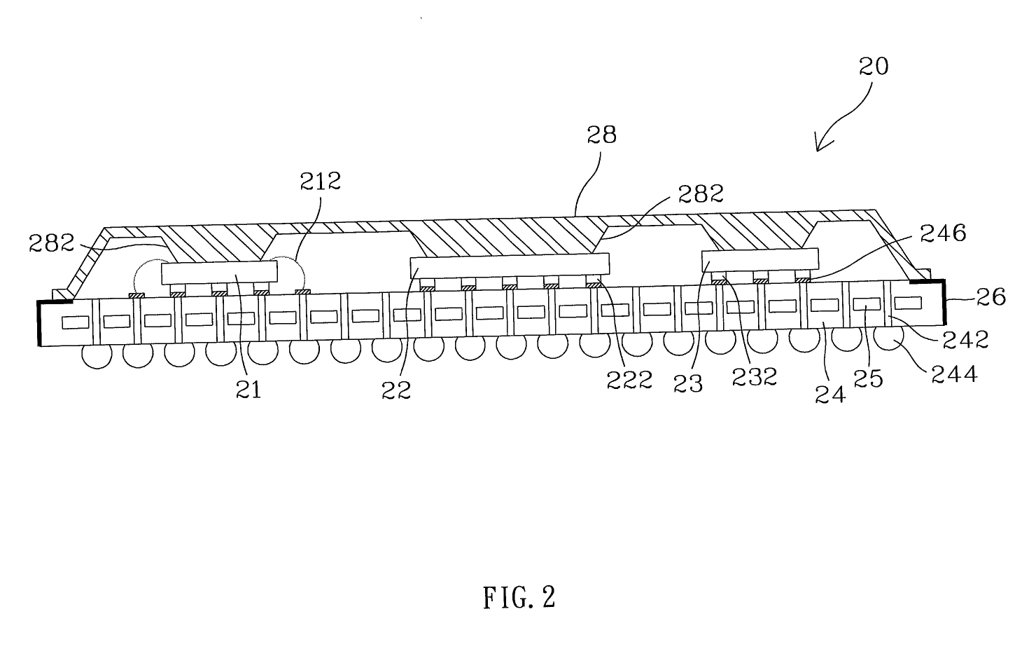

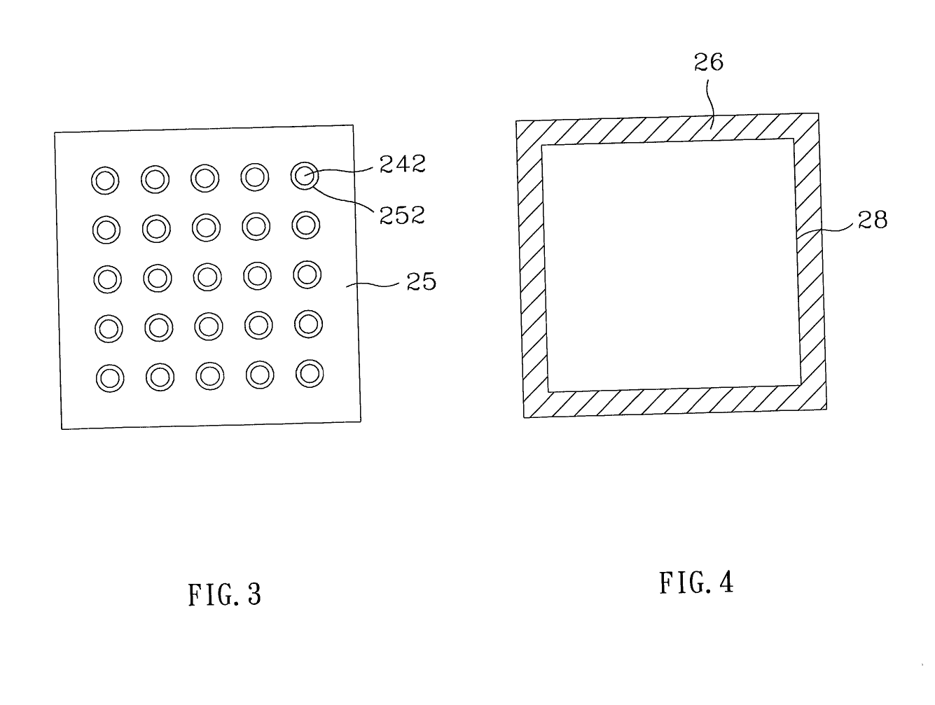

The present invention is characterized in that a heat-spreading plate and a substrate are exploited to increase heat-spreading effect of a chip and to prevent the chip from EMI. FIG. 2 shows an embodiment of the present invention. In an electronic device 20, a substrate 24 bears chips 21, 22, and 23. A conductive ring 26 is formed on the periphery of the substrate 24. The substrate 24 has a plurality of vias 242, each being connected to a solder ball 244. A metal layer 25 is formed in the substrate 24 with its periphery connected to the conductive ring 26. FIG. 3 shows a top view of the substrate 24 with the metal layer 25 as the cross-sectional plane. The metal layer 25 has a plurality of through holes 252 to let the vias 242 pass through so as to prevent them from short-circuiting with other vias 242.

To form the conductive ring 26, one can electroplate a layer of conductive metal such as copper or aluminum on the periphery of the substrate 24, or one can etch the periphery of the surface of the substrate 24 to let the internal conductive metal be exposed, and then electroplate conductive metal on the side walls of the substrate 24.

The surface of the substrate 24 has a plurality of bonding pads 246 respectively connected to the vias 242. Wires 212 formed by means of wire bonding are used to connect circuit contacts of the chip 21 to the bonding pads 246. Bumps 222 and 232 electrically connected to the bonding pads 246 are formed on the surfaces of the chips 22 and 23 to lead out signals. A cap 28 capable of conducting both electricity and heat covers over the chip 24. The periphery of the cap 28 is sealed with the conductive ring 26, as shown in FIG. 4. Raised parts 282 formed in the cap 28 contacts with the surfaces of the chips 21 to 23 so as to take heat away.

Through exact control of the thickness of the raised parts 282 formed in the cap 28, the possibility of crushing the chips 21 to 23 can be prevented. In other words, the present invention can apply to IC chips of various kinds of sizes. For instance, the technique of powder metallurgy is one method of fabricating the cap 28.

The periphery of the cap 28 is connected to the conductive ring 26 by means of reflow of solder paste or conductive glue such as silver glue to let them be sealed and electrically connected.

To sum up, because the cap 28 is sealed with the conductive ring 26 and the conductive ring 26 is connected to the metal later 25 of the substrate 24, they three form a shield of EMI for the chips 21 to 23 enclosed by them. Moreover, the metal layer 25 can be exploited to increase heat-spreading area.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

I claim:

1. A ball grid array package capable of increasing heat-spreading effect and preventing electromagnetic interference, comprising:
a ball grid array substrate;
a conductive ring formed on the periphery of said ball grid array substrate;
a metal layer formed in said ball grid array substrate, the periphery of said metal layer being connected to said conductive ring;
at least an IC chip arranged on said substrate; and
a cap capable of conducting both electricity and heat sealed with and electrically connected to said conductive ring, said cap covering over said chip, raised parts formed in said cap contacting with the surface of said chip.
